(19) United States
(12) Patent Application Publication
(10) Pub. No.: US 2018/0053870 A1
(43) Pub. Date: Feb. 22, 2018

(54) STRUCTURE FOR IMPROVING PHOTOVOLTAIC GENERATION AND MANUFACTURING METHOD OF THE SAME

(71) Applicant: Po-Ying Chen, Kaohsiung City (TW)

(72) Inventors: Po-Ying Chen, Kaohsiung (TW); I-Chin Chen, Kaohsiung (TW); I-Hsi Chen, Kaohsiung (TW)

(21) Appl. No.: 15/239,766

(22) Filed: Aug. 17, 2016

(51) Int. Cl. H01L 31/072; H01L 31/075; H01L 31/0256; H01L 31/0224; H01L 31/18

(52) U.S. Cl. CPC H01L 31/072; H01L 31/075; H01L 31/1804; H01L 31/022425; H01L 31/0256

(57) ABSTRACT

A photovoltaic structure includes a power generating unit and a conducting unit. The power generating unit includes a P-type semiconducting layer and an N-type semiconducting layer adjoined to the P-type semiconducting layer. The N-type semiconducting layer includes a plurality of N-type materials and a conductive material surrounding the plurality of N-type materials. The conducting unit includes a bottom layer adjoined to P-type semiconducting layer and a top layer adjoined to N-type semiconducting layer.

### BACKGROUND OF THE INVENTION

### 1. Field of the Invention

The present invention relates to a structure for appreciably improving photovoltaic generation output and a manufacturing method for the same, and more particularly to a photovoltaic generation structure provided with a sustainable enhancement of output efficiency.

### 2. Description of the Related Art

With technological advances, a wide diversity of electrical equipment has been developed, and the electricity demands are rapidly increasing. Currently, power generation facilities can be classified into three systems: thermal, hydroelectric and wind power generation.

Thermal power generation involves consuming abundant coal or fuel, and so it is not only expensive but also harms the environment and causes atmospheric pollution.

Hydroelectric power generation has strict geographical limitations, and accompanied with a shortage of water resources, the future of hydroelectric power generation is not optimistic. Conversely, wind power generation is limited by weather, and has extremely high requirements for wind velocity, and so it is not suitable for further development.

Photovoltaic power is a type of clean and sustainable green energy, and both academia and industry are working to develop photovoltaic generation, but nowadays the price of photovoltaic materials is high, and the photoelectric effect cannot be improved, so that photovoltaic generation is unable to be widely adopted at the present time.

From the above descriptions, certain problems still exist with current photovoltaic cells:

1. Poor photoelectric effect: some improvements are necessary for PIN junction of currently commercialized photovoltaic devices. One is that the efficiency of electron-hole pair irradiated by light can be improved, which is the first threshold of the photovoltaic generation processes and is called “temporary separation of electron-hole pairs”. Another one is that the electrons in the first threshold accumulate quickly and are connected to a system bus by conductive material, which is the second threshold of the photovoltaic generation processes and is called “permanent separation of electron-hole pairs”. The semiconducting material plays a conductor role in the structure of currently commercialized photovoltaic devices, and limitations of the second threshold are the primary cause of the poor photoelectric effect.

2. High manufacturing costs: in current photovoltaic cells, the I and N layers are formed on top of P-type base material by deposition, and in order to deposit the semiconducting material onto the P-type base material, higher energy is necessary.

Therefore, it is desirable that the conversion and power generating efficiency of photovoltaic cells is improved.

### SUMMARY OF EMBODIMENTS OF THE INVENTION

Therefore, an objective of an embodiment of the present invention is to provide a structure for improving photovoltaic generation output, comprising a power generating unit and a conducting unit.

The power generating unit includes a P-type semiconducting layer and an N-type semiconducting layer adjoined to the P-type semiconducting layer. The N-type semiconducting layer is composed of plural N-type materials and a conductive material by which the plural N-type materials are surrounded.

The conducting unit includes a conductive bottom layer adjoined to the P-type semiconducting layer and a conductive top layer adjoined to the N-type semiconducting layer.

Another technique of an embodiment of the present invention is that the plural N-type materials are nanoparticles.

Another technique of an embodiment of the present invention is that the state of the conductive material by which the plural N-type materials are surrounded is a liquid, a jelly or a colloid.

Another technique of an embodiment of the present invention is that the generating unit further includes an I-type semiconducting layer between the P-type semiconducting layer and the N-type semiconducting layer.

Another technique of an embodiment of the present invention is that the N-type semiconducting layer has a porous structure in which the conductive material is contained.

Another technique of an embodiment of the present invention is that plural containment apertures are formed on the surface of the N-type semiconducting layer and plural protruding columns are disposed alternately with plural containment apertures in which the conductive material are contained.

Another objective of an embodiment of the present invention is to provide a manufacturing method for a structure that improves photovoltaic generation output, comprising a P layer manufacturing step, an N layer manufacturing step and an electrode manufacturing step.

First, the P layer manufacturing step is performed, and a P-type semiconducting layer is manufactured.

Then, the N layer manufacturing step is performed, and a plurality of N-type nanoparticle materials are surrounded by a conductive material, with an N-type semiconducting layer being formed on top of the P-type semiconducting layer.

Finally, the electrode manufacturing step is performed, and a conductive top layer is disposed on top of the N-type semiconducting layer, and a conductive bottom layer is disposed below the P-type semiconducting layer.

Another technique of an embodiment of the present invention is that the N layer manufacturing step includes the following steps: first, an N layer material mixing step is performed, and the plurality of N-type nanoparticle materials are mixed with the conductive material. Then, an N layer depositing step is performed, the conductive material mixed with the plurality of N-type materials are deposited on the P-type semiconducting layer, so the N-type semiconducting layer is formed.

Another technique of an embodiment of the present invention is that the N layer manufacturing step includes the following steps: first, an N layer forming step is performed, and the plurality of N-type materials are formed on top of the P-type semiconducting layer. Then, an N layer sintering step is performed, and the plurality of N-type materials are sintered into a porous structure. Next, in an N layer infusing step, the liquid conductive material is infused into the porous structure, so that the N-type semiconducting layer is formed.

Another technique of an embodiment of the present invention is that forming the N-type semiconducting layer includes the following steps: first, a deposition step is performed, and the plurality of N-type materials are deposited on top of the P-type semiconducting layer. Then, an etching step is performed, and a plurality of containment apertures are formed on the surface of the N-type material. Then, a filling step is performed, and the conductive material is filled into the plurality of containment apertures. An advantage of embodiments of the invention is that, in contrast to conventional photovoltaic generation, the structure of the N-type material is rearranged by which the recovery probability of the electron-hole pair can be reduced and electrons can be quickly delivered to the system bus. This rearrangement includes: (1) the N-type material is ground into a powder, and (2) the powder is surrounded by a liquid, a jelly or a colloidal conductive material, so that when the powder is irradiated by light, separated electron-hole pairs are increased, and the electrons can be effectively directed upward by the conductive material, while the holes are directed downward, so that the entire power generating process can be completed by the conducting unit.

### BRIEF DESCRIPTION OF THE DRAWINGS

FIG. 1 is a schematic drawing of a structure depicting a first preferred embodiment according to the present invention;

FIG. 2 is a schematic drawing depicting a plurality of N-type materials patterned into an N-type semiconducting layer dispersed in a conductive material in the first preferred embodiment according to the present invention;

FIG. 3 is a schematic drawing depicting a pattern of an N-type material surrounded by a conductive material in the first preferred embodiment according to the present invention;

FIG. 4 is a schematic drawing depicting an energy level state of common intrinsic semiconductors;

FIG. 5 is a schematic drawing depicting an energy level state of common photovoltaic cells;

FIG. 6 is a schematic drawing depicting an energy level state of the first preferred embodiment according to the present invention;

FIG. 7 is a spectral graph depicting the light wavelengths used for photovoltaic generation;

FIG. 8 is a step flowchart depicting a manufacturing method of the first preferred embodiment according to the present invention;

FIG. 9 is a 3-D schematic drawing depicting a second preferred embodiment according to the present invention;

FIG. 10 is a schematic drawing depicting movement of electron-hole pairs irradiated by light in the second preferred embodiment according to the present invention;

FIG. 11 is a partial schematic drawing depicting a third preferred embodiment according to the present invention;

FIG. 12 is a diagram depicting power generation output of a third preferred embodiment device compared to conventional photovoltaic cells;

FIG. 13 is a step flowchart depicting a manufacturing method of the third preferred embodiment according to the present invention;

FIG. 14 is a cross-section schematic drawing depicting a fourth preferred embodiment according to the present invention;

FIG. 15 is an exploded view drawing depicting a 3-D shape of the fourth preferred embodiment according to the present invention, and

FIG. 16 is a step flowchart depicting a manufacturing method of the fourth preferred embodiment according to the present invention.

### DETAILED DESCRIPTION OF THE PREFERRED EMBODIMENTS

Specific structural and functional details disclosed herein will become apparent from the following descriptions of the four preferred embodiments of the present invention taken in conjunction with the accompanying drawings.

Before explaining the present invention in detail, it is to be understood that similar elements are labeled with the same reference numbers.

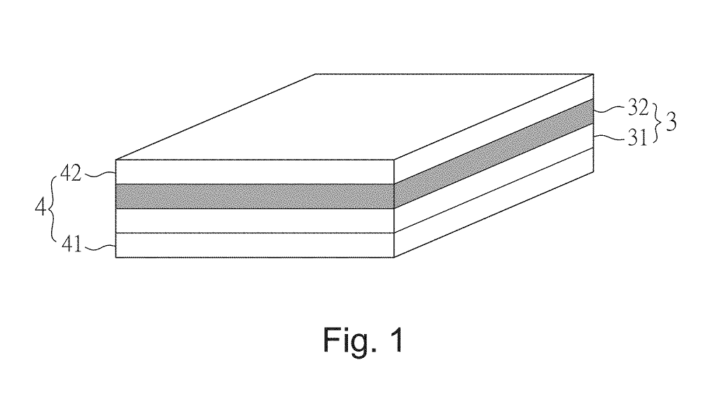

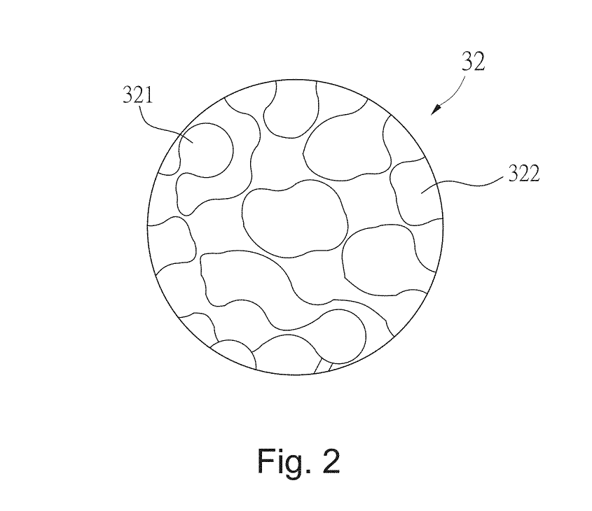

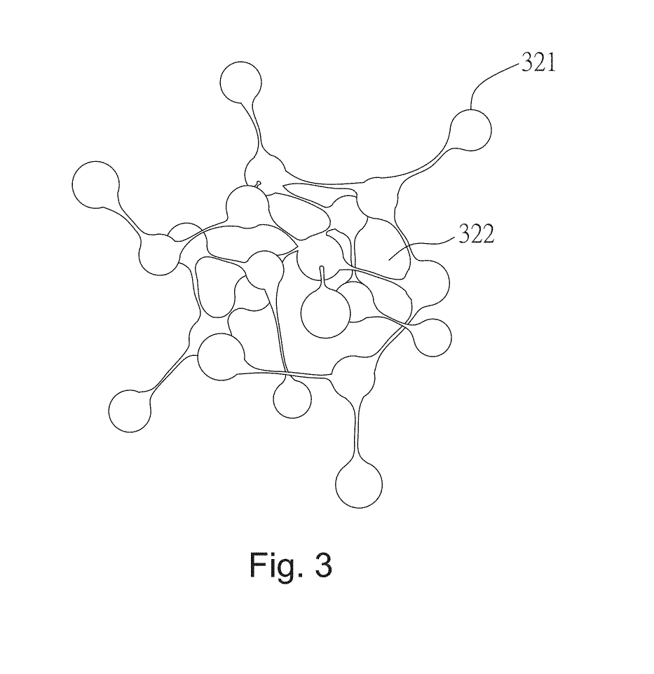

With reference to FIGS. 1, 2 and 3, a first embodiment of the present invention is provided, comprising a generating unit 3 and a conducting unit 4.

The generating unit 3 includes a P-type semiconducting layer 31 and an N-type semiconducting layer 32 adjoined to the P-type semiconducting layer 31. The N-type semiconducting layer 32 is composed of a plurality of N-type materials 321 and a conductive material 322 by which the plurality of N-type materials 321 are surrounded.

The plurality of N-type materials 321 are nanoparticles, and their ingredients include an intrinsic semiconductor material mixed with predetermined proportion of N-type dopant, so that the N-type nanoparticle material 321 can be surrounded by the conductive material 322.

In the first embodiment, the intrinsic semiconductor material doped with a predetermined proportion of P-type dopant is utilized by the P-type semiconducting layer 31, and its material is the same as the P-type structure of conventional photovoltaic cells.

The conductive bottom layer 41 and the conductive top layer 42 are made of grapheme, so that they are provided with the characteristics of transparency, and electrical and thermal conductivity. In practice, it will be appreciated that other materials provided with adequate transparency, and electrical and thermal conductivity can be used as well, and so should not be construed as limiting the invention.

Liquid sodium hydroxide, which has excellent electrical conductivity properties, is applied to the conductive material 322. In practice, the conductive material 322 presented in a thick jellied state can also be applied. Without external force, the molecules are cemented and immobile. For example, transparent and thick conductive glue can be applied as well. In addition, it will be appreciated that other liquid conductive materials can be applied to the conductive material 322 as well, and so should not be construed as limiting the invention.

The N-type nanoparticle materials are dispersed evenly in the conductive material 322 to form the N-type semiconducting layer 32, so that the conventional solid N-type material layer can be replaced. When the conductive material 322 by which the plural N-type materials 321 are surrounded is disposed on top of the P-type semiconducting layer 31, the generating unit 3 is turned into photovoltaic cells with a P-N interface. The photoelectric effect of photovoltaic cells is a commonly-used technique in the related industries, and so further explanation is not provided herein.

Basically, the generating efficiency of photovoltaic cells is given by (temporary separation of electron A−hole B pair)×(permanent separation of electron A−hole B pair), as determined by the inventor of the present invention from research and experiments. Notably, the term (temporary separation of electron A−hole B pair) results from molecules of a semiconductor being irradiated by the sunlight S, but the temporarily separated electron A−hole B pair may possibly disappear due to recovery.

Only a few electron A−hole B pairs can successfully be turned into a permanent separated electron A−hole B pair in the electric field of a P-N junction diode, and only when (permanent separation of electron A−hole B pair) is obtained, is power generation achieved.

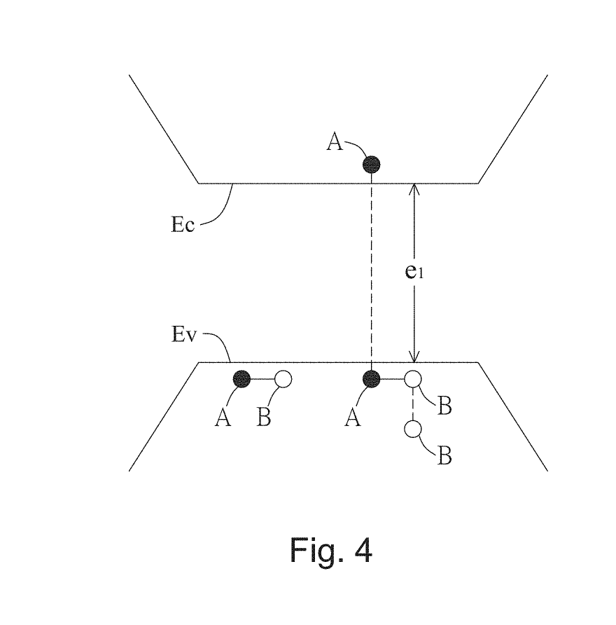

With reference to FIG. 4, an energy level state of an intrinsic semiconductor is depicted. Notably, the energy level e1 formed by the conduction band of an intrinsic semiconductor and the valence band EV renders that when the electron A−hole B pair is provided with enough energy from photons, the mass of the electron A is 1836 times lighter than the hole B, so it is possible that the electron A jumps into the conduction band EC, and a temporarily separated electron A—hole B pair can be obtained. When the electron A jumps from the valence band EV to the conduction band EC, the hole B still stays in the valence band EV, and, at this moment, there are two options for the electron A in the high-energy conduction band EC, including: (1) leaving or (2) going back to the low-energy valence band EV. If leaving is chosen, assistance of the electric field of P-N junction diode and conductive material are necessary, and the electron A can advance to a next stage, which is a permanent separation of electron A—hole B pair. However, if the second option (back to the low-energy valence band EV) is chosen, the power generation will fail. The power generation thus works by the above processes.

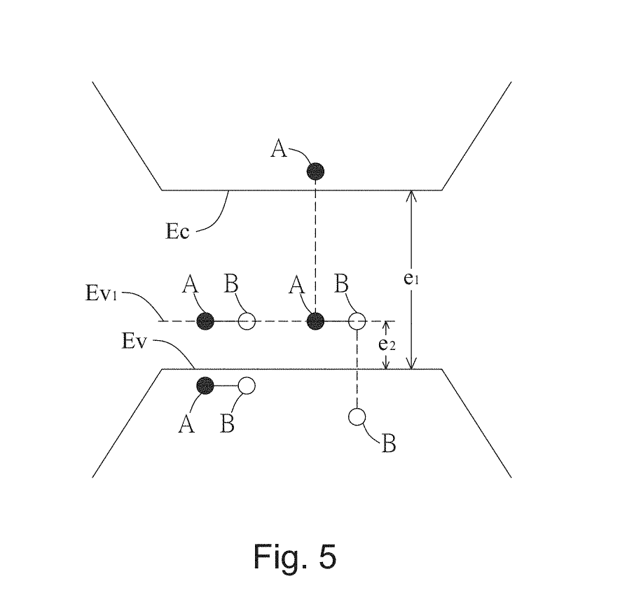

With reference to FIG. 5, an energy level state of conventional photovoltaic cells doped with P-N impurities is depicted. Because of doping with P-N impurities, the valence band EV of the intrinsic material can be advanced into a virtual extrinsic valence band EV1, the energy level of the photovoltaic cell is equal to an energy level e1 minus the virtual extrinsic energy level e2, the electron A can leave the hole B, and the energy needed by the free electron for jumping from virtual extrinsic valence band EV1 to the conduction band EC becomes less. This drawing shows why the doped P-N. Junction diode is reduced. This drawing shows why the P-N impurities improve the photovoltaic generation efficiency, but this technique has its limitations, so it can not appreciably improve the efficiency, and it is exactly the primary reason why the development of current photovoltaic cells efficiency is stalled.

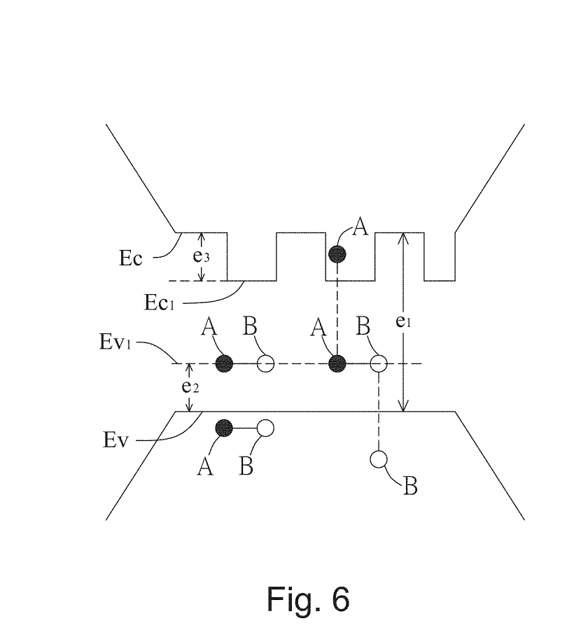

With reference to FIG. 6, a structure of the plurality of N-type materials 321 surrounded by a liquid conductive material is depicted. When the semiconductor is processed into nanoparticles, its energy level will be changed. The twisted downward conduction band EC will be induced by this process (the jag-shaped region of the conduction band EC in FIG. 6), and turns into the twisted conduction band EC1. Because of the P-N impurities, the virtual extrinsic valence band EV1 (depicted as dotted line above the valence band EV in FIG. 6) are formed above the valence band EV of the intrinsic material, and the energy level of the material is equal to the energy level e1 minus the virtual extrinsic energy level e2, and minus the twisted energy level e3, so that the energy required by the electron A for leaving the hole B and jumping from the virtual extrinsic valence band EV1 into the twisted conduction band EC1 to be a free electron A is greatly reduced. This means that a low energy spectrum of light is also capable of exciting the electron A in the virtual extrinsic valence band EV1 to jump into the twisted conduction band EC1, and power generation can thus be obtained.

From the above descriptions, temporary separated electron A—hole B pairs occur when light impinges upon the semiconductor material, and the proportion of temporary separated electron A—hole B pairs is decided by the energy level. The smaller the energy level is, the larger the proportion is. The energy level can be changed according to the concentration of impurities and the nanotechnology of semiconductor material: (1) the virtual extrinsic energy level will be produced by increased concentration of impurities; (2) the conduction band EC will be twisted downward because of the nanotechnology of the semiconductor material.

Notably, permanent separated electron A−hole B pair occurs only on the condition that electron A−hole B pair temporarily separates. The above description explains that the electron A in the conduction band EC is taken out quickly with the assistance of a high electrical conductive material. Otherwise, the electron A in the conduction band EC will stay too long because of a low electrical conductive material. A long hesitation period (the time taken by the electron A for temporary stay) is not good for the separation of electron A and hole B, because the electron A will go back to the valence band EV and recover with hole B, and hence the proportion of temporary and permanent electron A−hole B pairs will be appreciably reduced.

It is worth mentioning that the N-type semiconducting layer 32 is the main place for improving the photovoltaic output, and many orders of magnitude for temporary separation of electron A−hole B pairs are produced when the collision between sunlight S and N-type nanoparticle material 321 occurs, which is a better method than conventional production in bulk. When the plurality of N-type nanoparticle materials 321 (including semiconductor and dopant) are surrounded by the introduced excellent electrical conductive material (the conductive material 322), the permanent separation of electron A−hole B pairs will occur only when the semiconductor material is surrounded by the conductive material 322, and electron A is directed to the conductive top layer 42, and hole B is directed to the conductive bottom layer 41, so that power will be provided by the electrical potential difference between the conductive top layer 42 and the conductive bottom layer 41.

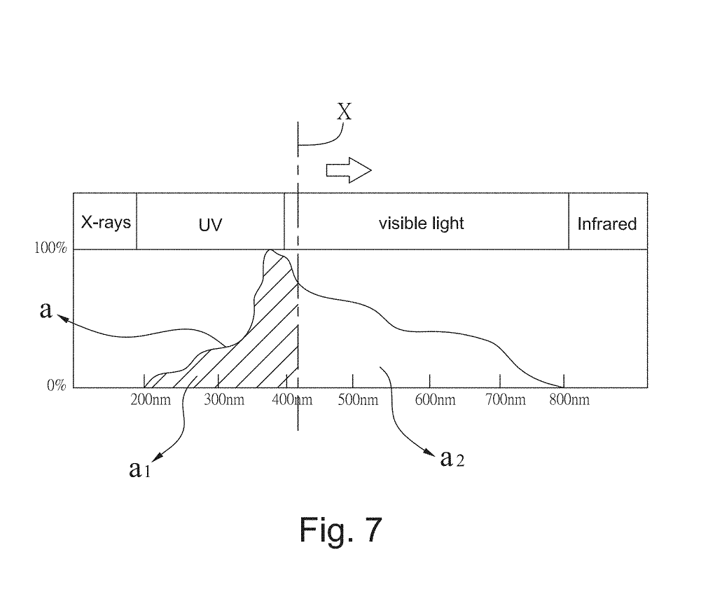

With reference to FIG. 7, a spectrum is depicted. Notably, the wavelength of visible light is between 390 nm and 700 nm. The region surrounded by the curve a is the total range of the light spectrum. The shorter the frequency, the higher the energy. The spectrum region a1 can excite electrons which starts from the left hand of the distinguishing line X in the spectral graph and ends at the curve a, and it is the electromagnetic frequency of conventional photovoltaic cells. Conventional photovoltaic cells only can use high-energy electromagnetic frequencies having high frequencies to excite electron A to generate power. The spectrum region a2 cannot, however, excite electrons which starts from the right hand of the distinguishing line X in the spectral graph and ends at the curve a, and light wave of a2 cannot excite any electrons in the semiconductor material.

As the particles of N-type materials 321 in the N-type semiconducting layer 32 become smaller, the distinguishing line X will move to the right, and the number of temporary separated electron A−hole B pairs in the N-type semiconducting layer 32 will be appreciably increased. When embodiments of this invention are applied, it can be imagined that a wider range of the spectrum can be utilized to excite the electrons A, and in the future, power can be generated by infrared or near infrared regions, so that the output of photovoltaic generation can be appreciably improved.

Once the N-type material 321 of the N-type semiconducting layer 32 is processed into nanoparticles, the plurality of N-type nanoparticle materials 321 can be surrounded by the conductive material 322, and the electron A−hole B pairs can be turned from temporary separations into permanent separations. When the electron A−hole B pairs become permanently separated, the electrons A and the holes B can be accumulated by the conductive unit 4 for power generation.

The equation for calculating the output of photovoltaic generation is expressed as:

E=(A)×(B), where

E is the total photovoltaic efficiency, (A) is the efficiency of temporarily separated electron A−hole B pairs, and (B) is the efficiency of permanently separated electron A−hole B pairs. Notably, (A) will be affected by the particle size of N-type material 321 in the N-type semiconducting layer 32. When the size of the N-type material 321 is smaller, the ratio of (A) is higher. (B) is decided by the characteristic of the conductive material 322 by which the N-type materials 321 are surrounded in the N-type semiconducting layer, and especially when ratio of (1) electrical conductivity or (2) transparency is raised, the ratio of (B) is higher.

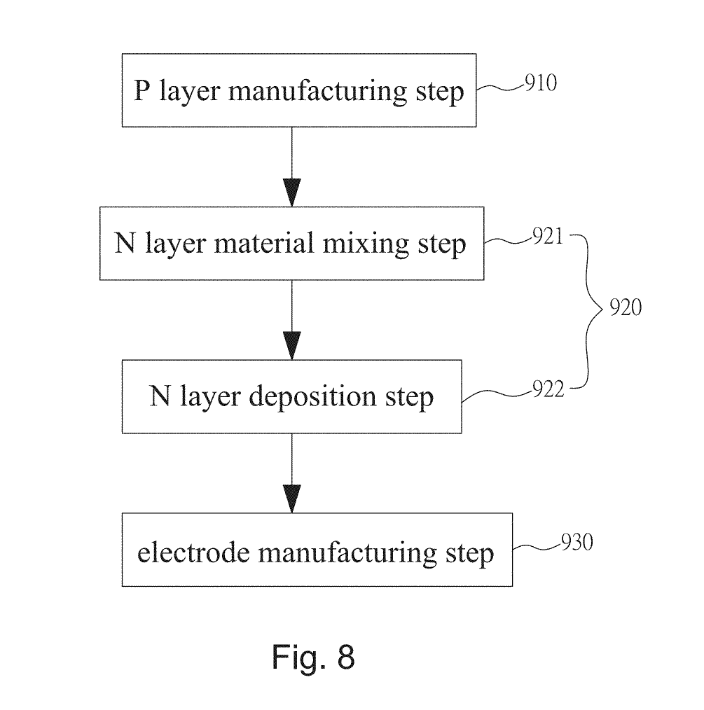

With reference to FIG. 8, a manufacturing method of the first preferred embodiment is depicted, comprising a P layer manufacturing step 910, an N layer manufacturing step 920, and an electrode manufacturing step 930.

First, the P layer manufacturing step is performed. An intrinsic base material is prepared, which is doped with a P-type extrinsic material by diffusion. For example, the intrinsic base material is made of silicon, and P-type extrinsic material is made of boron, so that a P-type semiconducting layer 31 is made from the intrinsic base material. The manufacturing method of P-type semiconducting layer 31 is a common technique in the field, and so further explanation is not provided herein.

Then, the N layer manufacturing step is performed, and the plurality of nanoparticle N-type materials 321 are surrounded by conductive material 322, and an N-type semiconducting layer 32 is formed on top of the P-type semiconducting layer 32. Moreover, the N layer manufacturing step 920 in the first preferred embodiment further includes an N layer material mixing step 921, and an N layer deposition step 922.

Next, an N layer material mixing step 921 is performed. The plurality of nanoparticle intrinsic materials are mixed with a plurality of nanoparticle N-type extrinsic materials to become an N-type material 321. When the intrinsic material is made of silicon, the N-type extrinsic material can be selected from arsenic or phosphorous, and the plurality of nanoparticle N-type materials 321 can be mixed evenly with the conductive material 322. Notably, the conductive material can be selected from sodium hydroxide, or other jellied or colloidal transparent conductive gels.

Then, an N layer coating step 922 is performed. The conductive material 322 mixed with the plurality of N-type materials 321 is coated on top of the P-type semiconducting layer 31 to form the N-type semiconducting layer 32. Preferably, transparent barrier ribs (not depicted in the drawing) can be disposed around the N-type semiconducting layer 32, so that the liquid conductive material 322 can be enclosed.

Finally, the electrode manufacturing step is performed. The conductive top layer 42 and the conductive bottom layer 41 are made of grapheme in various embodiments. Preferably, the conductive bottom layer 41 is disposed below the P-type semiconducting layer 31 by screen printing, and the conductive top layer 42 is disposed on top of the N-type semiconducting layer 32. Finally, the conductive material can be screen printed onto the transparent base material (not depicted in the drawings), and the liquid N-type semiconducting layer 32 is surrounded by the conductive top layer 42, while the N-type semiconducting layer 32 is enclosed by the conductive top layer 42 and bather ribs. The liquid enclosing technique is known in the field, and so further explanation is not provided herein.

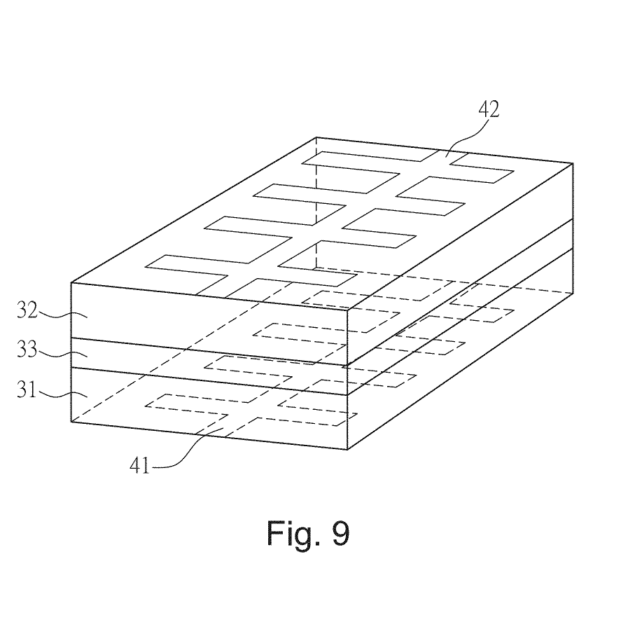

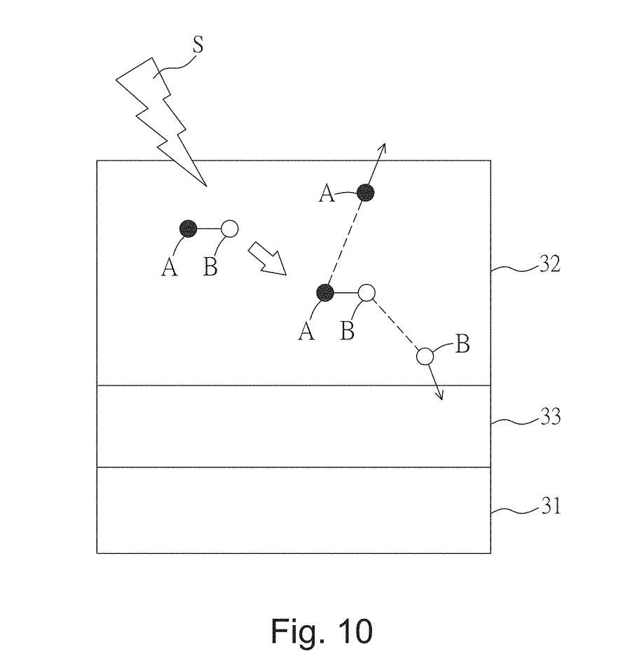

With reference to FIGS. 9 and 10, a second preferred embodiment according to the present invention is depicted, which is similar to the first embodiment, and so common features are not described again. A difference is that the generating unit 3 further includes an I-type semiconducting layer between the P-type semiconducting layer 31 and the N-type semiconducting layer 32. The material of the I-type semiconducting layer 33 is the same as the I-type structure in conventional photovoltaic cells. Moreover, the conductive top layer 42 is formed as system bus on top of the N-type semiconducting layer 32, and the conductive bottom layer 41 is formed as a system bus below the P-type semiconducting layer 31.

With respect to the second preferred embodiment, it is noted that in current solid structures a P-type semiconducting layer 31 and an I-type semiconducting layer 33, an absorption layer for sunlight S is made of the conductive material 322, which is surrounded by a plurality of nanoparticle N-type materials. After absorbing the sunlight S, the temporarily separated electron A−hole B pairs generated from the N-type semiconducting layer 32 in the generating unit 3 will be captured instantly by the conductive material 322, and turned into permanently separated electron A−hole B pairs. In the second preferred embodiment, the separation ratio of electron A−hole B pairs is controlled by the thickness of the I-type semiconducting layer, and this ration is (γ).

The intrinsic semiconducting layer can be formed on top of the P-type semiconducting layer 31 by the I-type semiconducting layer 33 by way of an enhanced plasma chemical vapor deposition process. The production of the I-type semiconducting layer 33 on the P-type semiconducting layer 31 is a common technique in the field, and so further explanation is not provided herein.

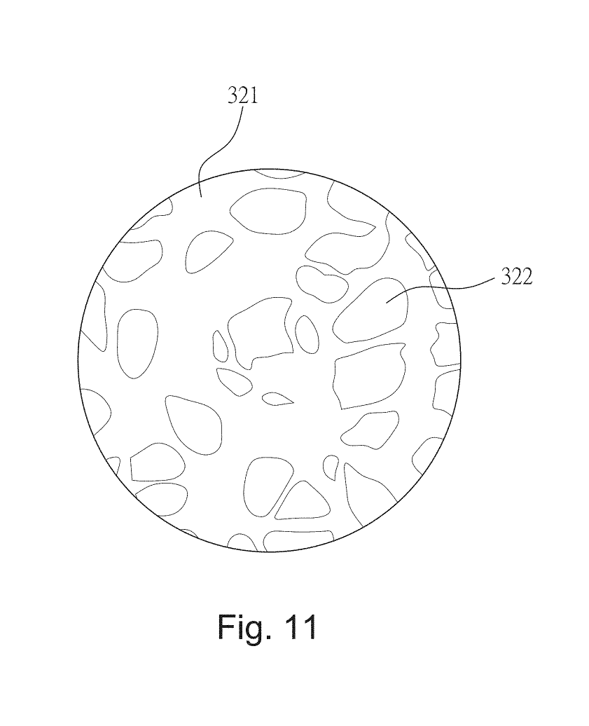

With reference to FIGS. 9 and 11, a third preferred embodiment according to the present invention is depicted, which is similar to the second embodiment, and so common features are not described again. A difference is that the N-type semiconducting layer 32 is a porous structure, in which the conductive material 322 is contained. Notably, the porous structure of the N-type semiconducting layer 32 is made using a low-temperature sintering process, and the structure formed is like bone cells or coral, and a plurality of apertures in the porous structure connect to each other. The porous structure can be made using a low-temperature sintering process, which is a common technique in the field, and so further explanation is not provided herein.

It is noted that the plurality of apertures in the N-type semiconducting layer 32 connect to each other, and be infused with the liquid conductive material 322, so that the conductive material 322 fills the plurality of apertures in the N-type semiconducting layer 32, and the plurality of N-type material 321 can be surrounded by the conductive material 322. When the N-type semiconducting layer 32 is irradiated by the sunlight S, the electron A−hole B pairs will be produced by the N-type material 321, and the electrons A and holes B will be separated by the electric field of the conductive material 322 and P-N interface, so that power can be provided.

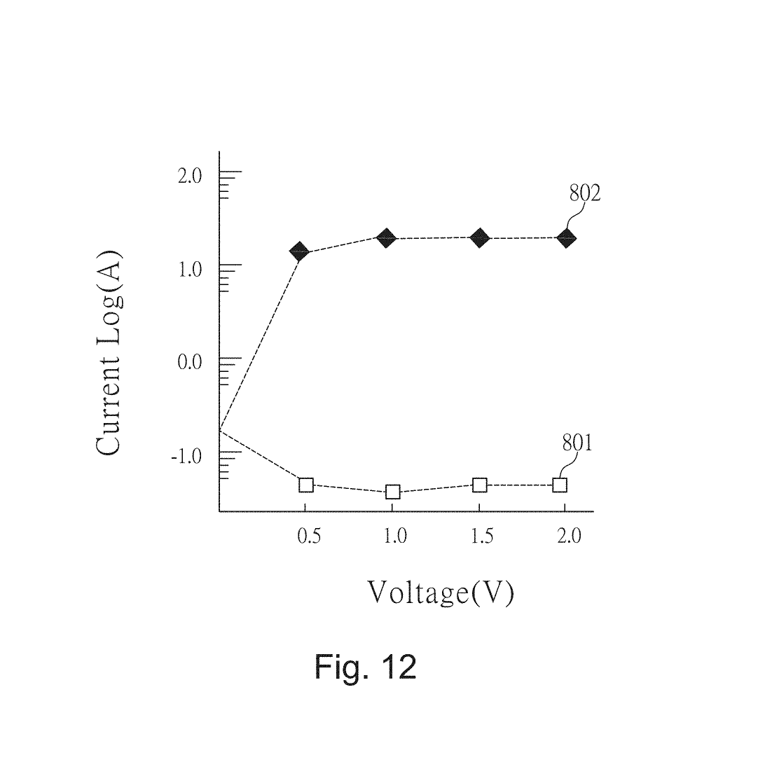

With reference to FIG. 12, a diagram of experimental data between the third preferred embodiment and conventional photovoltaic generation is depicted. Lateral axis is voltage, and the longitudinal axis is the log of current, curve 801 is a generating curve of a conventional photovoltaic generation device, and curve 802 is a generating curve of the third preferred embodiment. Notably, the N-type semiconducting layer 32 in the third preferred embodiment is made by the process that the N-type material 321 is made of silicon with added 2% P2O5, and the porous structure is made by low-temperature sintering, and the apertures connect to each other, and are infused with the conductive material 322 made of a NaOH solution. Compared to the conventional photovoltaic generation device, the output of the conductive bottom layer 41 and conductive top layer 42 in the third preferred embodiment is appreciably increased hundred times over the prior art, and the power can be provided stably.

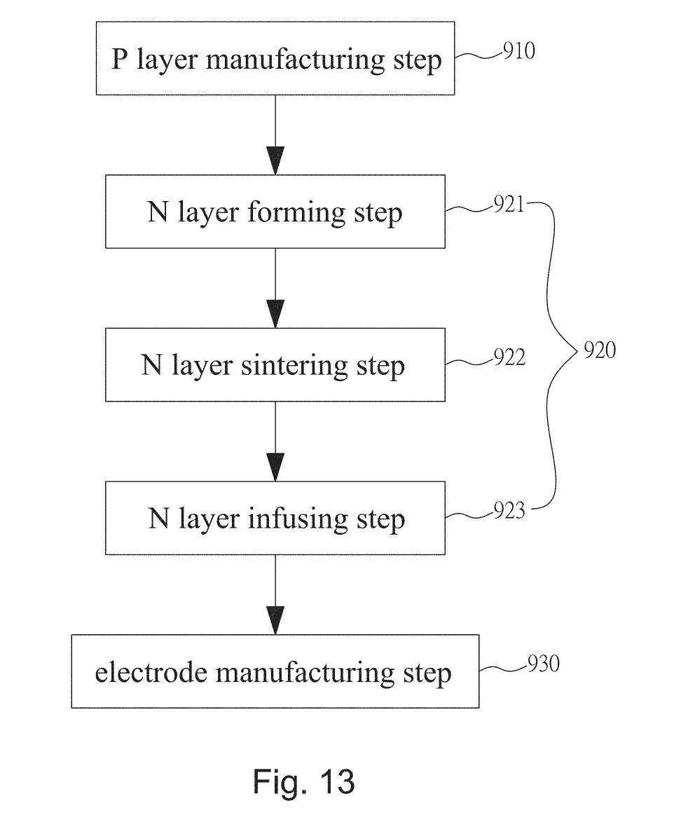

With reference to FIG. 13, a manufacturing method of the third preferred embodiment is depicted, including a P layer manufacturing step 910, an N layer manufacturing step 920, and an electrode manufacturing step 930. The manufacturing method of the third preferred embodiment is similar to the first embodiment, and so common features are not described again. A difference is that in the P layer manufacturing step 910, the I-type semiconducting layer 33 is formed on top of the P-type semiconducting layer 31 using an enhanced plasma chemical vapor deposition process, and the N layer manufacturing step 920 includes the following steps:

First, an N layer forming step 921 is performed. The plurality of N-type materials are mixed with water and disposed on top of the I-type semiconductor layer 33. After remaining for a while, the water is vaporized, and a ceramic blank layer organized by the plurality of N-type materials 321 is formed on top of the I-type semiconductor layer 33.

Then, an N layer sintering step 922 is performed. The plurality of N-type materials are sintered into a porous structure. The plurality of N-type materials 321 undergo a low-temperature sintering to form structure like bone cells or coral, and those apertures connect to each other.

Finally, in an N layer infusing step 923, the liquid conductive material 322 is infused into the N-type semiconductor layer 32, so that it can sink into the apertures of the porous structure, and the N-type semiconductor layer 32 is formed. The generating unit 3 with a P-I-N structure is formed by the N-type semiconductor layer 32, P-type semiconductor layer 31, and I-type semiconductor layer 33.

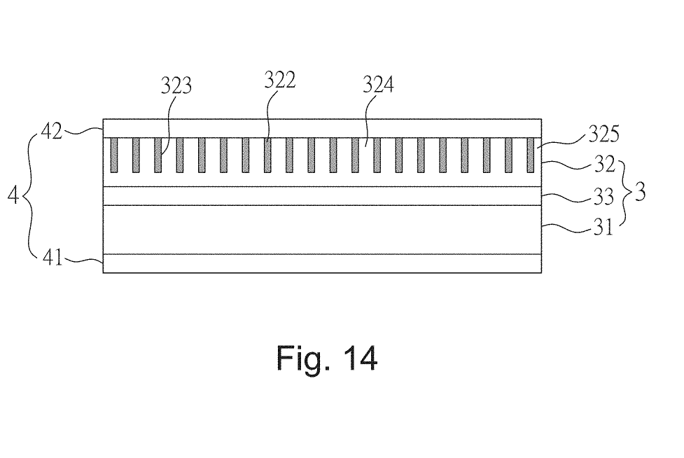

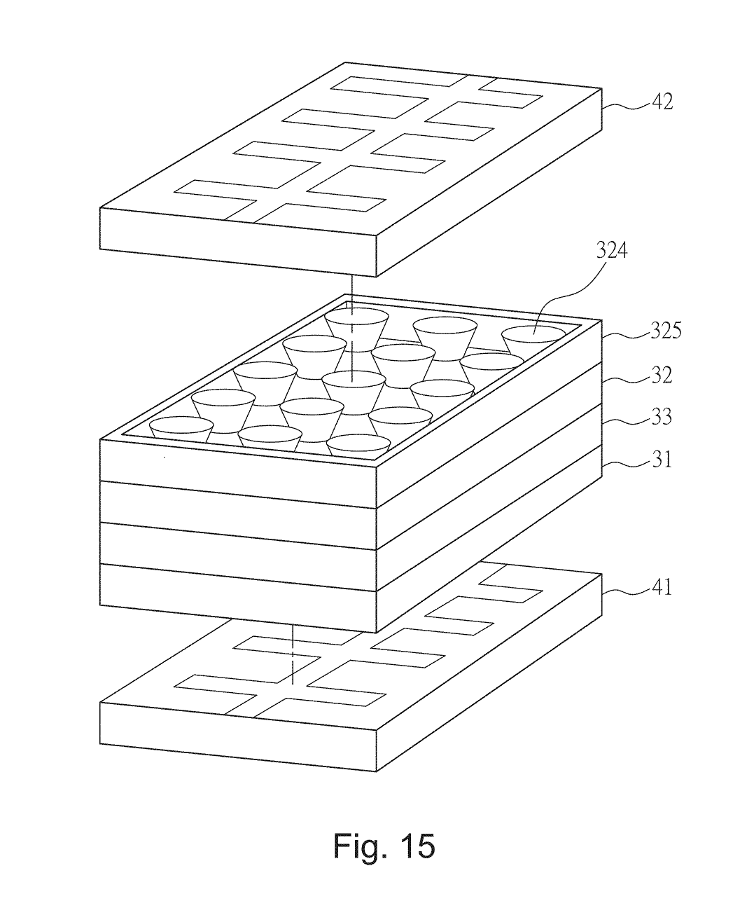

With reference to FIGS. 14 and 15, a fourth preferred embodiment according to the present invention is depicted, which is similar to the third embodiment, and so common features are not described again. A difference is that the plurality of containment apertures 323 are formed on the surface of the N-type semiconductor layer 32, the plurality of protruding columns 324 are disposed alternately with the plurality of containment apertures 323, and the conductive material 322 is contained in the containment apertures 323.

The N-type semiconductor layer 32 is the N layer of a conventional photovoltaic generation structure, and its partial volume is removed by laser engraving, and the plurality of containment apertures 323 are formed on the surface of the N-type semiconductor layer 32, and connect to each other, so that the plurality of island-like protruding columns 324 will be formed by the rest of the N-type material 321 on the surface of the N-type semiconductor layer 32. The protruding columns 324 are nanoparticles which form barrier ribs 325 around the surface of the N-type semiconductor layer 32. In practice, other engraving methods also can be applied as well, and so should not be construed as limiting the invention.

When the liquid conductive material 322 is infused into the surface of the N-type semiconductor layer 32, which is enclosed by the barrier rib 325, and the plurality of island-like nanoparticle protruding columns 324 surrounded by the conductive material 322 form the N-type semiconductor layer 32, and the generating unit 3 will be formed like a P-I-N structure. In practice, it is appreciated that the generating unit 3 with the P-I-N structure, the conductive bottom layer 41 and the conductive top layer 42 can be enclosed by a transparent material, so the plurality of island-like nanoparticle protruding columns 324 can be surrounded by the conductive material 322, and so should not be construed as limiting the invention.

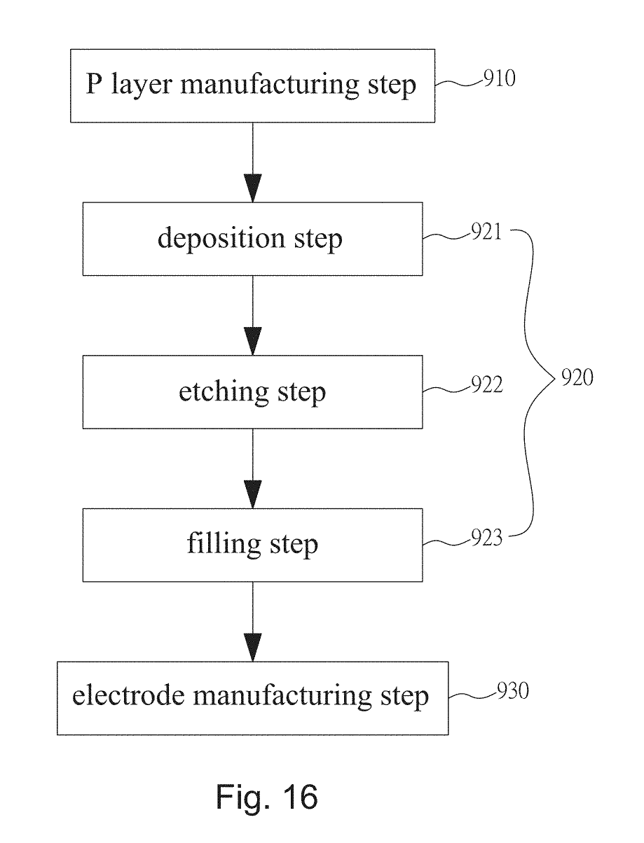

With reference to FIG. 16, a manufacturing method of the fourth preferred embodiment is depicted, which is similar to the third embodiment, and so common features are not described again. A difference is that the N layer manufacturing step 920 includes the following steps:

First, a deposition step 921 is performed, and a plurality of N-type materials 321 are disposed on top of the I-type semiconducting layer 33. The N-type materials 321 can be formed on top of the I-type semiconducting layer 33 using a semiconductor deposition technique, which is the same as for the N layer in a conventional photovoltaic cell with a P-I-N structure, and is common in the field, so that further explanation is not provided herein.

Then, an etching step 922 is performed. A plurality of containment apertures 323 are formed on the surface of the N-type material 321. Preferably, a partial volume of the N-type material 321 is removed by way of a laser engraving process to form a plurality of containment apertures 323 and a plurality of island-like protruding columns 324. Moreover, the bather ribs 325 are left to surround the surface of the N-type semiconductor layer 32, so that the liquid conductive material 322 is enclosed, which is left to stay in the plurality of containment apertures 323. In practice, it is appreciated that in the generating unit 3 with a P-I-N structure, the conductive bottom layer 41 and the conductive top layer 42 can be enclosed by a transparent material, and so should not be construed as limiting the invention.

Finally, a filling step 923 is performed, and the liquid conductive materials 322 is filled into the plurality of containment apertures 323 on the N-type semiconductor layer 32, so that the nanoparticle protruding columns 324 are surrounded by the conductive material 322.

Although four preferred embodiments are disclosed, they all focus on P-N or P-I-N structures for photovoltaic cells, and so by only reconstructing the N-type semiconductor layer 32, the ratio of temporary and permanently separated electron A−hole B pairs can be raised, and the output efficiency of photovoltaic generation can be improved. Moreover, another advantage of embodiments of the present invention is the modification of the types and particle sizes of the N-type material 321, accompanying with the conductive material 322, a sustainable power output efficiency can be obtained.

With the aforementioned descriptions, the following benefits of embodiments of the present invention can be obtained:

1. Capturing the Electron A Effectively

In embodiments of the present invention, the N-type material 321 is ground or processed into a nanoparticle powder, and mixed with a liquid, jelly, or colloidal conductive material 322, so that a photovoltaic generation device with a P-I-N structure irradiated by sunlight S can excite more electrons A that can be directed to and captured by the conductive material 322, and avoid recovery effects by remaining too long.

2. Reducing Manufacturing Costs

In embodiments of the present invention, the N-type material 321 is processed into a nanoparticle powder, and mixed with a liquid or colloidal conductive material 322, which can be directly applied onto the surface of the I-type semiconducting layer 33, instead of a conventional deposition method, the N-type material 321 can be produced successfully.

In conclusion, reconstructing the N-type semiconducting layer 32 to become the best structure of a generating layer is emphasized by embodiments of the present invention. In embodiments of the present invention, the conventional solid N layer is replaced with the conductive material 322 surrounded by a plurality of nanoparticle N-type materials 321, so that the electrons A can be increased by the photoelectric effect and captured by the N-type materials 321, and directed to the outside quickly to avoid recovery. The ratio of temporarily and permanently separated electron A−hole B pairs can be increased, and the output efficiency of the photovoltaic generation device can be improved, so that objectives of the present invention can be obtained.

Embodiments of the present invention can be continually developed through three parameters: (1) the options of N-type materials 321 are numerous; (2) the size of the nanomaterials can be modified; (3) the conductivity of the conductive material 322 surrounding the plurality of N-type materials 321 can be improved.

The foregoing detailed description is merely in relation to four preferred embodiments and shall not be construed as limiting the invention. It is to be understood that many other possible modifications and variations can be made without departing from the spirit and scope of the invention as hereinafter claimed.

What is claimed is:

1. A photovoltaic structure comprising:
a power generating unit, including a P-type semiconducting layer, an N-type semiconducting layer adjoined to the P-type semiconducting layer, the N-type semiconducting layer comprising a plurality of N-type materials, and a conductive material surrounding the plurality of N-type materials; and
a conducting unit, including a conductive bottom layer adjoined to the P-type semiconducting layer and a conductive top layer adjoined to the N-type semiconducting layer.

2. The device as claimed in claim 1, wherein the plurality of N-type materials are nanoparticles.

3. The device as claimed in claim 1, wherein a state of the conductive material surrounding the plurality of N-type materials is a liquid, a jelly or a colloid.

4. The device as claimed in claim 1, wherein the generating unit further includes an I-type semiconducting layer between the P-type semiconducting layer and the N-type semiconducting layer.

5. The device as claimed in claim 1, wherein the N-type semiconducting layer has a porous structure containing the conductive material.

6. The device as claimed in claim 1, wherein a plurality of containment apertures are formed on the surface of the N-type semiconducting layer and a plurality of protruding columns are disposed alternately with a plurality of containment apertures containing the conductive material.

7. A manufacturing method for a photovoltaic structure, comprising the following steps:
a P layer manufacturing step, wherein a P-type semiconducting layer is manufactured;
an N layer manufacturing step, wherein a plurality of N-type nanoparticle materials are surrounded by a conductive material, and an N-type semiconducting layer is formed on top of the P-type semiconducting layer; and
an electrode manufacturing step, wherein a conductive top layer is disposed on top of the N-type semiconducting layer, and a conductive bottom layer is disposed below the P-type semiconducting layer.

8. The method as claimed in claim 7, wherein the N layer manufacturing step including the following steps:
an N layer material mixing step, wherein the plurality of N-type materials are mixed with the conductive material; and
an N layer deposition step, wherein the conductive material mixed with the plurality of N-type materials are deposited on the P-type semiconducting layer, forming the N-type semiconducting layer.

9. The method as claimed in claim 7, wherein the N layer manufacturing step includes the following steps:
an N layer forming step, wherein the plurality of N-type materials are formed on top of the P-type semiconducting layer;
an N layer sintering step, wherein the plurality of N-type materials are sintered into a porous structure; and
an N layer infusing step, wherein the liquid conductive material is infused into the porous structure, forming the N-type semiconducting layer.

10. The method as claimed in claim 7, wherein the N layer manufacturing step includes the following steps:
a deposition step, wherein the plurality of N-type materials are disposed on top of the P-type semiconducting layer;
an etching step, wherein a plurality of containment apertures are formed on the surface of the N-type material; and
a filling step, wherein the conductive material is filled into the plurality of containment apertures.
